(19) United States
(12) Patent Application Publication
(10) Pub. No.: US 2012/0018797 A1
(43) Pub. Date: Jan. 26, 2012

(54) NONVOLATILE MEMORY DEVICE, AND METHODS OF MANUFACTURING AND DRIVING THE SAME

(76) Inventors: Tea-Kwang YU, Hwaseong-si (KR); Yong-Tae KIM, Yongin-si (KR); Byung-Sup SHIM, Yongin-si (KR); Yong-Kyu LEE, Gwacheon-si (KR); Bo-Young SEO, Suwon-si (KR); Ji-Hoon PARK, Seongnam-si (KR)

(21) Appl. No.: 13/168,257

(22) Filed: Jun. 24, 2011

(30) Foreign Application Priority Data
Jul. 22, 2010 (KR) 10-2010-0071059

(51) Int. Cl. H01L 29/792

(52) U.S. Cl. 257/324; 257/E29.309

(57) ABSTRACT

A nonvolatile memory device includes a device isolation film defining an active region in a semiconductor substrate, a pocket well region formed in an upper portion of the active region and having a first conductivity type, a gate electrode formed on the active region and extending to intersect the active region, a tunnel insulating film, a charge storage film, and a blocking insulating film sequentially disposed between the active region and the gate electrode, a source region and a drain region respectively formed in a first region and a second region of the active region exposed on both sides of the gate electrode, and each having a second conductivity type opposite to the first conductivity type, a pocket well junction region formed in the first region adjacent to the source region and contacting the pocket well region, and having the first conductivity type, and a metal silicide layer formed in the first region and contacting the source region and the pocket well junction region.

### CROSS-REFERENCE TO RELATED APPLICATIONS

This application claims the benefit of Korean Patent Application No. 10-2010-0071059, filed on Jul. 22, 2010, the disclosure of which is hereby incorporated by reference herein in its entirety.

### BACKGROUND

(i) Technical Field

The inventive concept relates to a nonvolatile memory device, and more particularly, to a nonvolatile memory device capable of increasing a degree of integration, a method of manufacturing the nonvolatile memory device, and a method of driving the nonvolatile memory device.

(ii) Description of the related art

While electronic devices become smaller, they may be required to process a significant amount of data. Accordingly, it may be necessary to increase the degree of integration of a nonvolatile memory device used in such electronic devices. However, since nonvolatile memory devices use a relatively high voltage, it may be difficult to increase the degree of integration due to a disturbance between adjacent cells.

Thus, there is a need in the art for a nonvolatile memory device, which may prevent disturbance during a program or erase operation, a method of manufacturing the nonvolatile memory device, and a method of driving the nonvolatile memory device.

### SUMMARY

Exemplary embodiments of the inventive concept provide a nonvolatile memory device, which may prevent disturbance during a program or erase operation, a method of manufacturing the nonvolatile memory device, and a method of driving the nonvolatile memory device.

According to an exemplary embodiment of the inventive concept, there is provided a nonvolatile memory device including: a device isolation film defining an active region in a semiconductor substrate, a pocket well region formed in an upper portion of the active region and having a first conductivity type, a gate electrode formed on the active region and extending to intersect the active region, a tunnel insulating film, a charge storage film, and a block insulating film sequentially disposed between the active region and the gate electrode, a source region and a drain region respectively formed in a first region and a second region of the active region exposed on both sides of the gate electrode, and each having a second conductivity type opposite to the first conductivity type. The nonvolatile memory device further includes a pocket well junction region formed in the first region adjacent to the source region and contacting the pocket well region, and having the first conductivity type and a metal silicide layer formed in the first region and contacting the source region and the pocket well junction region.

The device isolation film may be recessed to a predetermined depth from a surface of the semiconductor substrate, so that the active region protrudes beyond the device isolation film.

Edges of the active region protruding beyond the device isolation film may be rounded.

The pocket well region may have a lowermost surface between a lower surface and an upper surface of the device isolation film.

The nonvolatile memory device may further include: an isolation well region contacting a lower portion of the device isolation film and a lower portion of the pocket well region, and having the second conductivity type and a deep well region formed under the isolation well region and having the second conductivity type.

The isolation well region may extend and contact at least a portion of the pocket well region and at least a portion of the device isolation film.

The isolation well region may extend along a lower surface of the pocket well region, a lower surface of the device isolation film, and a side surface of the lower portion of the device isolation film, wherein the side surface of the lower portion of the device isolation film connects the lower surface of the pocket well region and the lower surface of the device isolation film.

The isolation well region may have a carrier concentration higher than a carrier concentration of the deep well region.

The isolation well region and the deep well region may contact each other to form a high-low junction due to a relatively high carrier concentration and a relatively low carrier concentration.

The isolation well region may have a carrier concentration that is at least twice as high as a carrier concentration of the deep well region.

The pocket well region and the isolation well region may directly contact each other to form a p-n junction.

The pocket well junction region may have a carrier concentration higher than a carrier concentration of the pocket well region.

The metal silicide layer may continuously extend from the source region and to pocket well junction region.

The metal silicide layer may include a sidewall portion contacting the source region and a bottom surface portion contacting the pocket well junction region in the first region, and a recess region is defined by the sidewall portion and the bottom surface portion.

The thickness of the sidewall portion and the thickness of the bottom surface portion of the metal silicide layer may be different from each other.

The nonvolatile memory device may further include a spacer layer contacting both side surfaces of the gate electrode, wherein the source region is located in a portion of the active region covered by the spacer layer, the pocket well junction region is located in a portion of the active region exposed by the gate electrode and the spacer layer, and the metal silicide layer is formed on the pocket well junction region and contacts a side surface of the source region.

A thickness of the metal silicide layer may be no less than a thickness of the source region.

The nonvolatile memory device may further include: an interlayer insulating layer formed on the active region and the gate electrode and completely covering the metal silicide layer, a conductive bit line contact plug passing through the interlayer insulating layer and electrically connected to the drain region and a conductive well contact plug passing through the interlayer insulating layer and electrically connected to the pocket well region.

A width of the first region may be less than a width of the second region in a direction perpendicular to a direction in which the gate electrode extends.

According to an exemplary embodiment of the inventive concept, there is provided a nonvolatile memory device including: a semiconductor substrate defining a cell region and a core/peripheral circuit region, an active region defined by and protruding beyond a device isolation film that is recessed to a predetermined depth from a surface of the semiconductor substrate in each of the cell region and the core/peripheral circuit region, a gate electrode formed on the active region and extending to intersect the active region, a pocket well region formed on an upper portion of the active region in the cell region and having a first conductivity type, a tunnel insulating film, a charge storage film, and a blocking insulating film sequentially disposed between the active region and the gate electrode in the cell region, a gate insulating film disposed between the active region and the gate electrode in the core/peripheral circuit region, a source region and a drain region respectively formed in a first region and a second region of the active region exposed on both sides of the gate electrode in the cell region, and each having a second conductivity type. The nonvolatile memory device further includes a pocket well junction region formed in the first region adjacent to the source region, and having the first conductivity type and a metal silicide layer formed in the first region and extending to contact the source region and the pocket well junction region. The active region, the gate insulating film, and the gate electrode constitute a high voltage transistor in the core/peripheral circuit region.

The nonvolatile memory device may further include: an isolation well region extending along lower surfaces of the device isolation film and the pocket well region in the cell region, and having a second conductivity type opposite to the first conductivity type; and a deep well region formed under the isolation well region in the cell region and having the second conductivity type.

According to an exemplary embodiment of the inventive concept, there is provided a method of driving the nonvolatile memory device, the method including applying a same potential to the source region and the pocket well region, when any one of a program operation of injecting charges into the charge storage film, an erase operation of removing the injected charges, and a read operation of reading the existence of the injected charges is performed.

When any one of the program operation and the erase operation is performed, the same potential may be applied to the source region, the drain region, and the pocket well region.

According to an exemplary embodiment of the inventive concept, there is provided a method of manufacturing a nonvolatile memory device, the method including: forming a device isolation film for defining an active region in a semiconductor substrate; forming a pocket well region having a first conductivity type in an upper portion of the active region, forming a charge storage structure by sequentially forming a tunnel insulating film, a charge storage film, and a block insulating film on the active region, forming a gate electrode, which extends to intersect the active region, on the active region with the tunnel insulating film, the charge storage film, and the blocking insulating film therebetween; forming a source region and a drain region each having a second conductivity type opposite to the first conductivity type respectively in a first region and a second region of the active region exposed on both sides of the gate electrode, and forming a pocket well junction region having the first conductivity type in the first region to be adjacent to the source region; and forming a metal silicide layer, which extends to contact the source region and the pocket well junction region, in the first region.

The forming of the source region and the drain region and the forming of the pocket well junction region may include: forming a first impurity region and a second impurity region each having the second conductivity type respectively in the first region and the second region; forming a third impurity region having the first conductivity type under the first impurity region; and forming a portion of the first impurity region as the metal silicide layer.

Before the forming of the third impurity region, the method may further include forming a spacer layer to cover both side surfaces of the gate electrode and to expose a portion of the first impurity region, wherein the forming of the third impurity region includes injecting impurities having the first conductivity type into the first region by using the gate electrode and the spacer layer as a mask.

The forming of the source region and the drain region and the forming of the pocket well junction region may include: forming a first impurity region and a second impurity region each having the second conductivity type respectively in the first region and the second region; forming a recess region passing through the first impurity region; forming a third impurity region having the first conductivity type in an exposed portion under a lower surface of the recess region; and forming an exposed portion of an inner surface of the recess region as the metal silicide layer.

Before the forming of the third impurity region, the method may further include forming a spacer layer to cover both side surfaces of the gate electrode and to expose a portion of the first impurity region, wherein the forming of the recess region includes removing an exposed portion of the first region by using the gate electrode and the spacer layer as an etch mask.

After the forming of the device isolation film, the method may further include removing a portion of the device isolation film in such a manner that the device isolation film is recessed to a predetermined depth from a surface of the semiconductor substrate and the active region protrudes beyond the device isolation film.

After the removing of the portion of the device isolation film, the method may further include forming round edges by rounding edges of the semiconductor substrate protruding beyond the device isolation film.

The forming of the round edges may include forming the round edges by using wet etching.

The forming of the round edges may include: oxidizing an exposed portion of the active region protruding beyond the device isolation film and removing an oxidized portion of the exposed portion of the active region.

After the removing of the portion of the device isolation film, the method may further include forming an isolation well region that extends along lower surfaces of the device isolation film and the pocket well region, and a deep well region that is formed under the isolation well region, wherein the isolation well region and the deep well region are formed to have the second conductivity type and a carrier concentration of the isolation well region is higher than a carrier concentration of the deep well region, the pocket well region and the isolation well region directly contact each other to form a p-n junction, and the isolation well region and the deep well region directly contact each other to form a high-low junction.

The forming of the gate electrode may include forming a plurality of the gate electrodes extending parallel to one another and spaced apart from one another alternatively by different distances, wherein the first regions are every other active regions selected from the plurality of the active regions exposed between the gate electrodes and wherein the second regions are the remaining active regions being between the first regions among the plurality of the active regions exposed between the gate electrodes.

The forming of the gate electrode may include forming the gate electrode in such a manner that a first width, which is a width of the first region, is less than a second width, which is a width of the second region, in a direction perpendicular to a direction in which the gate electrode extends.

According to an exemplary embodiment of the inventive concept, a method for manufacturing a nonvolatile memory device is provided. The method includes removing part of a semiconductor substrate to form a trench therein, filling the trench with an insulating material to thereby form a preliminary device isolation film in the trench which defines an active region in the semiconductor substrate, injecting impurities into an upper portion of the active region to form a pocket well region having a first conductivity type, removing a portion of the preliminary device isolation film from the trench to form a device isolation film such that the device isolation film has an upper surface that is higher than a lowermost surface of the pocket well region and edges of the active region protrude beyond the device isolation film, etching the active region such that the edges of the active region which protrude beyond the device isolation film become rounded edges, injecting impurities under the pocket well region to form a deep well region having a second conductivity type that is opposite to the first conductivity type, injecting impurities between the pocket well region and the deep well region to form an isolation well region having the second conductivity type between the pocket well region and the deep well region and wherein the isolation well region contacts a lower portion of the device isolation film and a lower portion of the pocket well region, forming a charge storage structure including a tunnel insulating film, a charge storage film and a blocking insulating film sequentially stacked on the active region and the device isolation film, forming a gate electrode on the charge storage structure, patterning the gate electrode and the charge storage structure to expose portions of the active region on both sides of the gate electrode. The portions of the active region exposed by the gate electrode constitute a first region and a second region. The method further includes forming a first impurity region and a second impurity region each having the second conductivity type in the first region and the second region, respectively of the active region exposed by the gate electrode, forming a spacer layer which covers side surfaces of the gate electrode and the charge storage structure, partially covers the first region and the second region and which exposes a portion of the first impurity region and the second impurity region, injecting impurities having the first conductivity type through the portion of the first impurity region exposed by the spacer layer to form a third impurity region and an unexposed portion of the first impurity region remains as a source region, fanning a metal silicide layer contacting the source region and the third impurity region, forming a fourth impurity region having the first conductivity type is formed in a part of the pocket well region, forming an interlayer insulating layer on the semiconductor substrate to cover the entire gate electrode and the portions of the active region exposed by the spacer layer, removing part of the interlayer insulating layer to form a first contact hole through which the second impurity region is exposed and a second contact hole through which the fourth impurity region is exposed and a portion of the first and second contact holes is self aligned and filling in the first contact hole and the second contact hole to form a bitline contact plug in the first contact hole and a well contact plug in the second contact hole. The bit line contact plug is electrically connected to the second impurity region and the well contact plug is electrically connected to the pocket well region through the fourth impurity region.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view illustrating an operation of defining an active region, according to an embodiment of the inventive concept;

FIG. 2 is a cross-sectional view illustrating an operation of forming a pocket well region, according to an embodiment of the inventive concept;

FIG. 3 is a cross-sectional view illustrating an operation of forming a device isolation film, according to an embodiment of the inventive concept;

FIG. 4 is a cross-sectional view illustrating an operation of rounding edges of the active region, according to an embodiment of the inventive concept;

FIG. 5 is a cross-sectional view illustrating an operation of forming a deep well region, according to an embodiment of the inventive concept;

FIG. 6 is a cross-sectional view illustrating an operation of forming an isolation well region, according to an embodiment of the inventive concept;

FIGS. 7A and 7B are cross-sectional views illustrating an operation of forming a gate electrode, according to an embodiment of the inventive concept;

FIG. 8A illustrates a cross-sectional view illustrating an operation of forming a first impurity region and a second impurity region, according to an embodiment of the inventive concept;

FIG. 8B illustrates a cross-sectional view illustrating an operation of forming a spacer layer, according to an embodiment of the inventive concept;

FIG. 9A is a cross-sectional view illustrating an operation of forming a third impurity region, according to an embodiment of the inventive concept;

FIG. 9B is a cross-sectional view illustrating an operation of forming a metal silicide layer, according to an embodiment of the inventive concept;

FIG. 9C is a cross-sectional view illustrating an operation of forming a bit line contact plug and a well contact plug, according to an embodiment of the inventive concept;

FIGS. 10A through 10D are cross-sectional views illustrating an operation of forming a third impurity region and a metal silicide layer, according to an embodiment of the inventive concept;

FIG. 11 is a cross-sectional view illustrating an operation of foaming a high voltage transistor, according to an embodiment of the inventive concept;

FIG. 12 is a plan view illustrating a positional relationship between the device isolation film, the active region, the bit line contact plug, the metal silicide layer, and the gate electrode, according to an embodiment of the inventive concept;

FIG. 13 is a table illustrating an operating voltage for explaining a method of driving the nonvolatile memory device, according to an embodiment of the inventive concept;

FIGS. 14 and 15 are conceptual views illustrating potentials applied to an adjacent unit cell when a selected unit cell of the nonvolatile memory device is driven, according to an embodiment of the inventive concept;

FIG. 16 is a block diagram of a nonvolatile memory device according to an embodiment of the inventive concept;

FIG. 17 is a block diagram of a memory card according to an embodiment of the inventive concept; and

FIG. 18 is a block diagram of an electronic system according to an embodiment of the inventive concept.

### DETAILED DESCRIPTION OF EXEMPLARY EMBODIMENTS

The inventive concept will now be described more fully with reference to the accompanying drawings, in which exemplary embodiments of the inventive concept are shown. Although exemplary embodiments have been described, those of ordinary skill in the art will readily appreciate that many modifications are possible in exemplary embodiments without materially departing from the novel teachings and advantages of exemplary embodiments. That is, specific structural and functional details disclosed herein are merely representative for purposes of describing exemplary embodiments. This inventive concept, however, may be embodied in many alternate forms and should not be construed as limited to only the exemplary embodiments set forth herein.

It will be understood that when an element, such as a layer, a region, or a substrate, is referred to as being “on”, “connected to” or “coupled to” another element, it may be directly on, connected or coupled to the other element or intervening elements may be present.

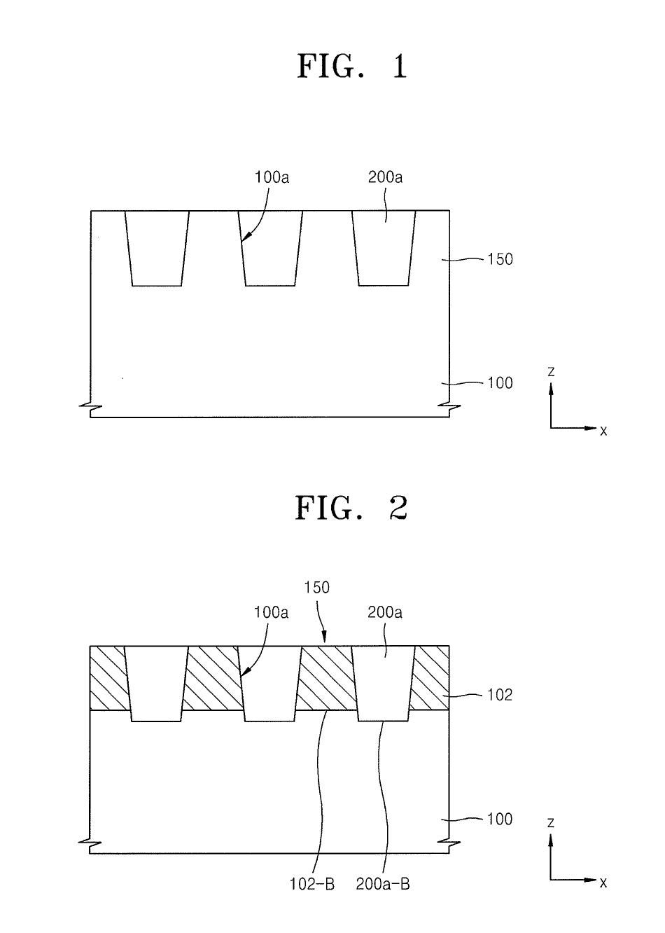

FIGS. 1 through 9 are cross-sectional views illustrating a method of manufacturing a nonvolatile memory device, according to an embodiment of the inventive concept.

FIG. 1 is a cross-sectional view illustrating an operation of defining an active region 150, according to an embodiment of the inventive concept.

Referring to FIG. 1, a part of a semiconductor substrate 100 is removed to form a trench 100a. The semiconductor substrate 100 may be, for example, a semiconductor substrate having a flat upper surface such as a general silicon substrate. Alternatively, the semiconductor substrate 100 may be a compound semiconductor substrate such as, for example, a silicon-on-insulator (SOI) substrate, a silicon-germanium substrate, or a gallium-arsenic substrate.

The trench 100a may be formed by performing, for example, photolithography. To form the trench 100a, a mask layer (not shown) for exposing a portion where the trench 100a is to be formed may be formed. The mask layer may be a hard mask or a photoresist such as, for example, a nitride film.

Next, the trench 100a is filled with an insulating material to form a preliminary device isolation film 200a. The preliminary device isolation film 200a may be formed of, for example, an oxide, a nitride, or a combination thereof. The preliminary device isolation film 200a may be, for example, a combination of a buffer oxide film, a trench liner nitride film, and a buried oxide film. The preliminary device isolation film 200a may be formed by, for example, forming an insulating material on the semiconductor substrate 100 to completely fill the trench 100a and performing planarization. The planarization for forming the preliminary device isolation film 200a may be achieved by, for example, performing chemical mechanical polishing (CMP).

If the mask layer is used to form the trench 100a, the planarization for forming the preliminary device isolation film 200a may be performed by using the mask layer as a stop film. Next, the mask layer is removed. The preliminary device isolation film 200a having an upper surface slightly higher than or almost parallel to an upper surface of the active region 150 may be formed.

The active region 150 may be a part of the semiconductor substrate 100 defined by the preliminary device isolation film 200a. The active region 150 may be a part of the semiconductor substrate 100 over a virtual plane extending from a lowermost portion of the preliminary device isolation film 200a.

FIG. 2 is a cross-sectional view illustrating an operation of forming a pocket well region 102, according to an embodiment of the inventive concept.

Referring to FIG. 2, impurities are injected into an upper portion of the active region 150 to form a pocket well region 102 having a first conductivity type. A lowermost surface 102-B of the pocket well region 102 may be higher than a lower surface 200a-B of the preliminary device isolation film 200a. That is, the pocket well region 102 may be formed in a portion of the active region 150 other than a lower end portion of the active region 150. The first conductivity type is a p-type or an n-type. If the semiconductor substrate 100 is a p-type semiconductor substrate or a p-type well region having a relatively low carrier concentration, the pocket well region 102 may be a p-type region having a relatively high carrier concentration.

For example, ion implantation, diffusion, or a combination thereof may be used to form the pocket well region 102. Impurities including, for example, boron (B) may be injected in such a manner that the pocket well region 102 is foamed as a p-type region. The impurity injection for forming the pocket well region 102 may be performed without forming a separate mask pattern. However, if a portion illustrated in FIG. 2 corresponds to a cell region of the nonvolatile memory device, a mask pattern for selectively preventing impurity injection may be used in a peripheral circuit region or a core region which is not shown.

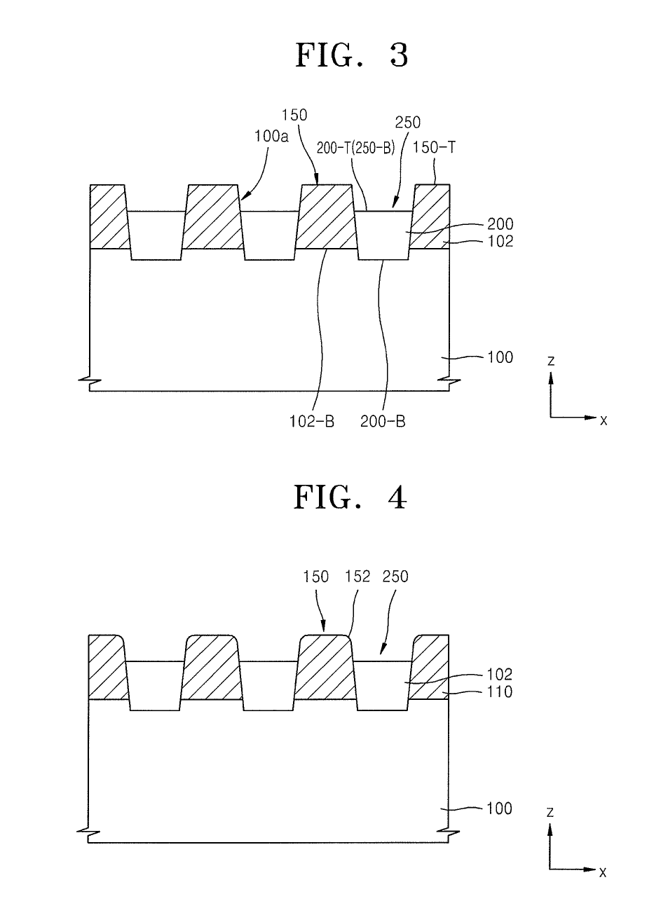

FIG. 3 is a cross-sectional view illustrating an operation of forming a device isolation film 200, according to an embodiment of the inventive concept.

Referring to FIG. 3, an upper portion of the preliminary device isolation film 200a illustrated in FIG. 2 is removed to form the device isolation film 200. When the upper portion of the preliminary device isolation film 200a is removed, a first recess region 250 recessed to a predetermined depth from an upper surface 150-T of the active region 150 is formed in the device isolation film 200. Accordingly, the active region 150 may protrude beyond the device isolation film 200. The first recess region 250 may have a lower surface 250-B that is higher than the lowermost surface 102-B of the pocket well region 102. That is, the device isolation film 200 may have an upper surface 200-T that is higher than the lowermost surface 102-B of the pocket well region 102. That is, the lowermost surface 102-B of the pocket well region 102 may be located between the upper surface 200-T and the lower surface 200-B of the device isolation film 200.

The depth of the first recess region 250 may be, for example, about 5 to about 50% of a thickness of the device isolation film 200. For example, if the thickness of the device isolation film 200 is about 3000 Å, the depth of the first recess region 250, that is an interval between the upper surface 150-T of the active region 150 and the upper surface 200-T of the device isolation film 200, may be about 150 to about 1500 Å.

The thickness of the pocket well region 102 and the thickness of the device isolation film 200 may be similar to each other. That is, accordingly, the depth of the first recess region 250 and the thickness of the lower end portion of the active region 150 where the pocket well region 102 is not formed may be similar to each other.

If an isolation well region, which will be explained later, is formed by ion implantation, in consideration of a projected range Rp of impurities injected according to materials used to form the pocket well region 102 and the device isolation film 200, the thickness of the pocket well region 102 and the thickness of the device isolation film 200 may be slightly different from each other. For example, if the pocket well region 102 is formed of silicon and the device isolation film 200 is a silicon oxide film, the thickness of the pocket well region 102 and the thickness of the device isolation film 200 may be determined in such a manner that projected ranges Rp of impurities in the silicon and the silicon oxide film are similar to each other.

For example, wet etching having a high etch selectivity between the active region 150 and the preliminary device isolation film 200a may be used to form the device isolation film 200. If the active region 150, that is, the semiconductor substrate 100, is formed of silicon and the preliminary device isolation film 200a is an oxide film, a wet etchant having a high etch selectivity between the silicon and the oxide film may be used.

A wet etch back process using, for example, a hydrofluoric acid (HF) solution may be performed to form the device isolation film 200. The HF solution may be obtained by, for example, mixing HF with water (H₂O) at a ratio of about 1:10 to about 1:1000 at room temperature. The HF solution may be used by, for example, allowing an object to be dipped therein or by being sprayed onto the object. Alternatively, for example, a buffered oxide etchant (BOE), which is a mixture of HF and ammonium fluoride (NH₄F), may be used instead of the HF solution. The device isolation film 200 having a desired thickness may be obtained by appropriately adjusting a time spent to use the HF solution.

FIG. 4 is a cross-sectional view illustrating an operation of rounding edges of the active region 150, according to an embodiment of the inventive concept.

Referring to FIG. 4, edges of the active region 150 protruding beyond the device isolation film 200 are rounded to form round edges 152. Wet etching using, for example, a mixture of ammonium hydroxide (NH₄OH), peroxide (H₂O₂), and H₂O (SC-1, Standard Clean 1) may be used to foam the round edges 152. Since angular edges of the active region 150 as shown in FIG. 3 are relatively often attacked by the mixture than other portions, the angular edges may be rounded. For example, NH₄OH, H₂O₂, and H₂O may be mixed at a ratio of about 1:1:5 to about 1:2:7 at a temperature of about 50 to about 80° C.

Alternatively, for example, to form the round edges 152, exposed portions of the active region 150 may be oxidized and then may be removed by wet etching. A resultant structure of FIG. 3 is exposed to an atmosphere to oxidize the exposed portions of the active region 150. For example, angular edges are readily oxidized, and an oxide film formed on the angular edges may form a round interface with a semiconductor material. When the oxide film formed on the angular edges of the active region 150 is removed by wet etching using HF, the round edges 152 may be exposed.

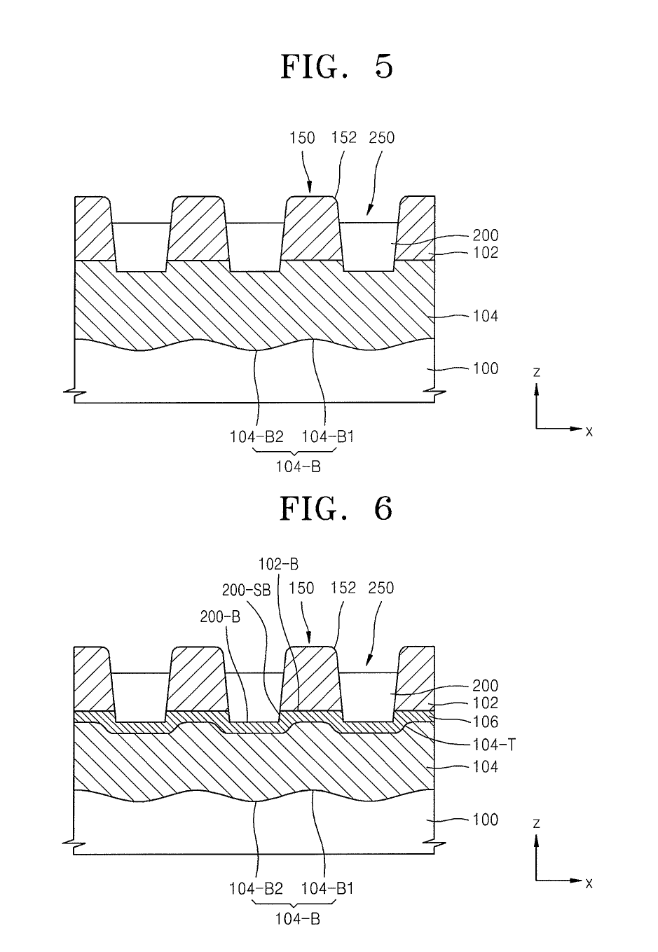

FIG. 5 is a cross-sectional view illustrating an operation of forming a deep well region 104, according to an embodiment of the inventive concept.

Referring to FIG. 5, impurities are injected under the pocket well region 102 to form the deep well region 104 having a second conductivity type that is opposite to the first conductivity type. While the pocket well region 102 and the deep well region 104 may contact each other as shown in FIG. 5, the pocket well region 102 and the deep well region 104 may be slightly spaced apart from each other. For example, ion implantation may be used to form the deep well region 104.

Due to a height difference between exposed surfaces of the active region 150 and the device isolation film 200, a lower surface 104-B of the deep well region 104 may be curved. For example, a portion of the deep well region 104 formed under the active region 150 protruding beyond the device isolation film 200 may have a relatively high lower surface 104-B1, and a portion of the deep well region 104 formed under the device isolation film 200 recessed relative to the active region 150 may have a relatively low lower surface 104-B2.

The second conductivity type may be an n-type or a p-type. If the first conductivity type is a p-type, the second conductivity type may be an n-type. Impurities including, for example, phosphorous (P) or arsenic (As) may be injected in such a manner that the deep well region 102 is formed as an n-type region. The impurity injection for forming the deep well region 102 may be performed without forming a separate mask pattern. However, if a portion illustrated in FIG. 5 corresponds to a cell region of the nonvolatile memory device, a mask pattern for selectively preventing impurity injection may be used in a peripheral circuit region or a core region which is not shown.

Phosphorous (P) or arsenic (As) ions may be implanted at a dose rate of, for example, about 10¹² ions/cm² or so to form the deep well region 104. As a result, the deep well region 104 may have a carrier concentration of, for example, about 10¹⁶/cm³ to about 10¹⁷/cm³.

FIG. 6 is a cross-sectional view illustrating an operation of forming an isolation well region 106, according to an embodiment of the inventive concept.

Referring to FIG. 6, impurities are injected between the pocket well region 102 and the deep well region 104 to form the isolation well region 106 having the second conductivity type. The isolation well region 106 may have a carrier concentration that is higher than that of the deep well region 104.

The second conductivity type may be an n-type or a p-type. If the first conductivity type is a p-type, the second conductivity type may be an n-type. Impurities including, for example, phosphorous (P) or arsenic (As) may be injected by ion implantation in such a manner that the isolation well region 106 is formed as an n-type region. The impurity injection for forming the isolation well region 106 may be performed without forming a separate mask pattern. However, if a portion illustrated in FIG. 6 corresponds to a cell region of the nonvolatile memory device, a mask pattern for selectively preventing impurity injection may be used in a peripheral circuit region or a core region which is not shown.

For example, to form the isolation well region 106, phosphorous (P) or arsenic (As) ions may be implanted at a dose rate of about 10¹³ ions/cm² to form the isolation well region 106. As a result, the isolation well region 106 may have a carrier concentration which is about two or more times higher than that of the deep well region 104 or whose order is greater than about 2. For example, if the carrier concentration of the deep well region 104 is about 10¹⁶/cm³, the carrier concentration of the isolation well region 106 may be 2×10¹⁶/cm³ to about 10¹⁸/cm³. Accordingly, if a conductivity type of the deep well region 104 is an n-type, a conductivity type of the isolation well region 106 may be, for example, an n+-type.

The isolation well region 106 may be formed to contact a lower portion of the device isolation film 200 and a lower portion of the pocket well region 102. For example, the isolation well region 106 may be formed to cover the lower portion of the device isolation film 200 and the lower portion of the pocket well region 102. The isolation well region 106 may be formed to extend while contacting at least a part of the pocket well region 102 and at least a part of the device isolation film 200.

The isolation well region 106 and the deep well region 104 may form a high-low junction. The term ‘high-low junction’ refers to a junction between a material having a relatively high carrier concentration and a material having a relatively low carrier concentration (disclosed in Solid State Electronic Devices, 6th Ed. By Ben G Streetman, p. 245, 2006 hereby incorporated by reference herein in its entirety). Also, the isolation well region 106 and the pocket well region 102 may form a p-n junction. For example, if conductivity types of the pocket well region 102, the isolation well region 106, and the deep well region 104 are respectively a p-type, an n+-type, and an n-type, the pocket well region 102 and the isolation well region 106 may form a p-n+junction, and the isolation well region 106 and the deep well region 104 may form a n+-n junction, that is, a high-low junction.

The isolation well region 106 may directly contact the pocket well region 102 and the deep well region 104 by being sandwiched between the pocket well region 102 and the deep well region 104. Like the deep well region 104, a lower surface of the isolation well region 106 may be curved due to a height difference between the exposed surfaces of the device isolation film 200 and the active region 150.

Accordingly, the isolation well region 106 may be formed to surround the lower surface 102-B of the pocket well region 102 and a surface of the lower portion of the device isolation film 200 which protrudes beyond the pocket well region 102. For example, the isolation well region 106 may be formed to extend along the lower surface 102-B of the pocket well region 102, the lower surface 200-B of the device isolation film 200, and a side surface 200-SB of the lower portion of the device isolation film 200 connecting the lower surface 102-B of the pocket well region 102 and the lower surface 200-B of the device isolation film 200. Also, the isolation well region 106 may be formed to surround an upper surface of the deep well region 104. For example, an upper surface of the isolation well region 106 may contact a surface of the lower portion of the device isolation film 200 and a lower surface of the pocket well region 102. Also, a lower surface of the isolation well region 106 may contact the upper surface of the deep well region 104.

If ion implantation is used to form the isolation well region 106, a projection range Rp of injected impurities may be similar to or slightly greater than a thickness of the device isolation film 200 and/or a thickness of the pocket well region 102. Accordingly, the isolation well region 106 may be formed to cover the lower portion of the device isolation film 200 and the lower portion of the pocket well region 102.

If the pocket well region 102 and the deep well region 104 are formed to be spaced apart from each other, the isolation well region 106 may be formed in a space between the pocket well region 102 and the deep well region 104. However, if the pocket well region 102 and the deep well region 104 are formed not to be spaced apart from each other, or even if the pocket well region 102 and the deep well region 104 are formed to be spaced apart from each other, the isolation well region 106 may be formed to include a part of a portion where the pocket well region 102 or the deep well region 104 is formed.

In this case, a carrier concentration slightly varies according to a location of the isolation well region 106. However, even in this case, an ion concentration of injected ions may be determined in such a manner that the isolation well region 106 has a carrier concentration higher than that of the deep well region 104. That is, if a portion of the isolation well region 106 is foamed on a portion where the pocket well region 102 is formed, an ion concentration of ions injected into the isolation well region 106 may be determined by considering compensation with the pocket well region 102 having the first conductivity type. That is, the isolation well region 106 may be formed to have a carrier concentration higher than that of the pocket well region 102.

Here, the term ‘carrier concentration’ may refer to the concentration of impurities injected into a specific region. Alternatively, if impurities having different conductivity types are injected into a specific region, the term ‘carrier concentration’ may refer to a concentration difference between the impurities having the different conductivity types, that is, a value resulting from compensation.

The thickness of the isolation well region 106 perpendicular to a surface of the semiconductor substrate 100 may be less than a thickness of the deep well region 104. Accordingly, the pocket well region 102, the isolation well region 106, and the deep well region 104 may be formed to have a p-n+-n (or n-p+-p) structure. Accordingly, since a p-n+ junction or a p+-n junction is formed between adjacent pocket well regions 102, the adjacent pocket well regions 102 may be electrically isolated from each other due to a high potential barrier. Accordingly, even though a design rule is reduced to increase the degree of integration, cells of the nonvolatile memory device formed between the adjacent pocket well regions 102 may be electrically isolated.

Since the electrical isolating of the pocket well regions 102 by using the isolation well region 106 and the deep well region 104 results from a height difference between the active region 150 and the device isolation film 200, a complex process does not need to be added.

Although the round edges 152, the deep well region 104, and the isolation well region 106 are formed in FIGS. 4 through 6, the present embodiment is not limited thereto. That is, the deep well region 104 or/and the isolation well region 106 may be first formed and then the round edges 152 may be formed, or the isolation well region 106 may be first formed and then the deep well region 104 may be formed.

Alternatively, after the deep well region 104 or/and the isolation well region 106 are formed, the round edges 152 may be formed during a process of forming a sacrificial oxide film for coping with damage to the surface of the active region 150 caused during ion implantation, during a process of the sacrificial oxide film, and during a cleaning process.

Accordingly, as long as a resultant structure illustrated in FIG. 6 is finally formed, an order in which the round edges 152, the deep well region 104, and the isolation well region 106 are formed may not be limited.

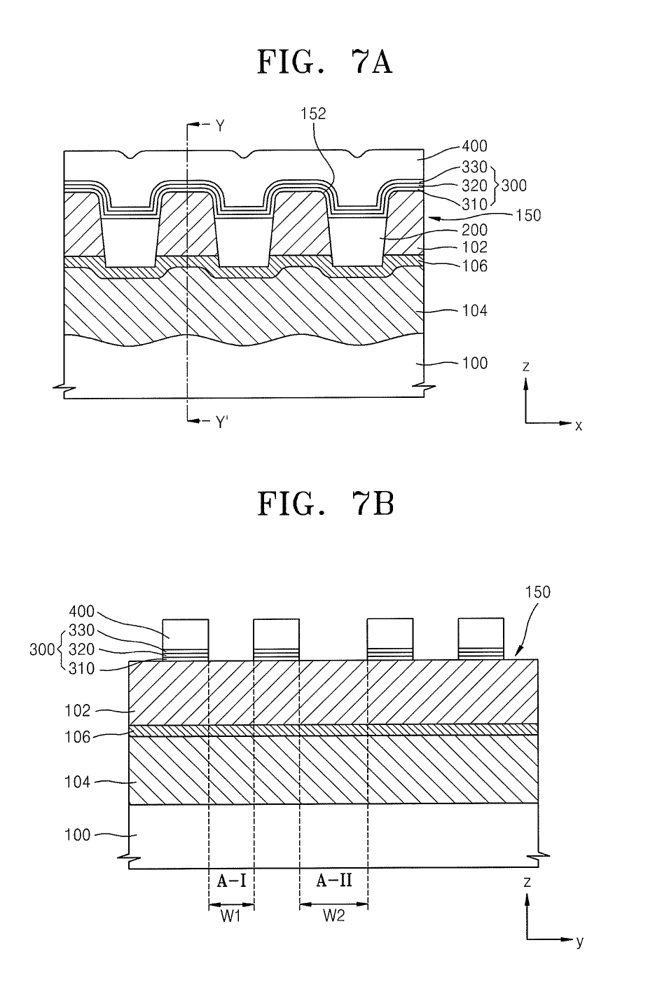

FIGS. 7A and 7B are cross-sectional views illustrating an operation of forming a gate electrode 400, according to an embodiment of the inventive concept. In detail, FIG. 7A is a cross-sectional view showing the same location as that of FIGS. 1 through 6, and FIG. 7B is a cross-sectional view taken along line Y-Y′ of FIG. 7A.

Referring to FIGS. 7A and 7B, a charge storage structure 300 including, for example, a tunnel insulating film 310, a charge storage film 320, and a blocking insulating film 330, and a gate electrode 400 formed on the charge storage structure 300 are formed on the semiconductor substrate 100, that is, on the active region 150 and the device isolation film 200. The charge storage structure 300 and the gate electrode 400 may be formed to extend, for example, in a first direction (x direction). Also, each of the charge storage structure 300 and the gate electrode 400 may be a plurality of line patterns which are extended parallel to one another and are disposed to be spaced apart from one another in, for example, a second direction (y direction) that is different from the first direction. The first direction and the second direction may be, for example, perpendicular to each other.

The charge storage structure 300 and the gate electrode 400 may be formed to cover the semiconductor substrate 100, and then patterned by using, for example, photolithography or the like to expose the active region 150, thereby forming a plurality of line patterns which are disposed to be spaced apart from one another in the second direction.

Portions of the active region 150 exposed on both sides of one gate electrode 400 may be a first region A-I and a second region A-II. A first width W1, which is a width of the first region A-I, and a second width W2, which is a width of the second region A-II, in the second direction, that is, a direction perpendicular to a direction in which the gate electrode 400 extends, may be the same as or different from each other.

The first regions A-I may be every other active regions selected from the plurality of the active regions 150 exposed between the gate electrodes 400 and the second regions A-II may be the remaining active regions being between the first regions A-I among the plurality of the active regions 150 exposed between the gate electrodes 400. Also, the first width W1 may be a width of a space between a plurality of alternately selected gate electrodes exposing the first region A-I, and the second width W2 may be a width of a space between a plurality of gate electrodes exposing the second region A-II and located between the alternately selected plurality of gate electrodes.

If the first width W1 and the second width W2 are the same, the gate electrode 400 may be a plurality of line patterns which are disposed to have the same pitch. If the first width W1 and the second width W2 are different from each other, the gate electrode 400 may be a plurality of line patterns which have the same line width and are disposed to alternately have different pitches, that is, are disposed to alternately have different space widths.

If the first width W1 and the second width W2 are different from each other, the first width W1 may be less than the second width W2. That is, the first region A-I may have a smaller width than the second region A-II in a direction perpendicular to a direction in which the gate electrode 400 extends. As will be described later, a region having a higher value, for example, the second region A-II, may be formed to contact a contact plug such as a bit line contact plug. A region having a smaller value, for example, the first region A-I, may be formed not to contact a contact plug but to be covered by an interlayer insulating film.

The tunnel insulating film 310 may be formed to cause a tunnel effect, and to have a thickness of, for example, about 30 to about 800 Å. For example, the tunnel insulating film 310 may include a silicon oxide (SiO₂) or a high-k oxide film such as a hafnium or zirconium oxide film, but the present embodiment is not limited thereto.

The charge storage film 320 may be formed to have a thickness of, for example, about 20 to about 200 Å, and may be formed roughly in two ways. If a conductor is used for the charge storage film 320, the charge storage film 320 acts as a floating gate. In this case, the charge storage film 320 may be, for example, a conductor including doped polysilicon or a metal.

If an insulator is used for the charge storage film 320, the charge storage film 320 acts as a trap layer. The charge storage film 320 acting as a trap layer may be formed of a material having a dielectric constant that is higher than that of a silicon oxide film and lower than that of a blocking insulating film that will be explained later. For example, if a silicon oxide film has a dielectric constant of about 3.9, the charge storage film 320 may be formed of a material having a dielectric constant higher than about 3.9, for example, a silicon nitride film having a dielectric constant of about 6. The charge storage film 320 may be formed to include a nitride film such as, for example, a silicon nitride film, an aluminum nitride film, or a silicon oxynitride film. Alternatively, the charge storage film 320 may be, for example, a nano dot layer including nano dots.

The block insulating film 330 may be formed of an excellent insulating material to prevent charges stored in the charge storage film 320 from leaking to the gate electrode 400. The blocking insulating film 330 may be formed to include, for example, a metal oxide film including aluminum, hafnium, zirconium, or the like, a metal silicate film including aluminum, hafnium, zirconium, or the like, or a silicon oxide film. For example, the blocking insulating film 330 may be a single film, or a multi-layer film including two or more of a metal oxide film including aluminum, hafnium, zirconium, or the like, a metal silicate film including aluminum, hafnium, zirconium, or the like, and a silicon oxide film. The blocking insulating film 330 may be, for example, an amorphous insulating film, but may include a crystalline metal oxide film or a crystalline metal silicate film. Also, if the blocking insulating film 330 is a multi-layer film, a crystalline film may constitute the multi-layer film, or a crystalline film and an amorphous film may constitute the multi-layer film.

The gate electrode 400 may include a conductive film, for example, doped polysilicon, a metal film, a metal silicide film, or a combination thereof. If the gate electrode 400 is foamed of polysilicon, the gate electrode 400 may be formed by depositing polysilicon, which is not doped with impurities, by using, for example, low-pressure chemical vapor deposition (LPCVD) at a temperature of 500 to 700° C., and ion-implanting arsenic (As) or phosphorous (P) so as to make the polysilicon conductive. Alternatively, the gate electrode 400 may be formed by, for example, doping polysilicon with impurities and depositing the impurity-doped polysilicon by using an in-situ process.

As described above, if a conductor is used for the charge storage film 320, a flash memory which is a floating gate type nonvolatile memory device may be formed. On the other hand, if an insulator is used for the charge storage film 320, a charge trap type flash memory which is a floating trap type nonvolatile memory device may be formed.

A portion of an interface between the gate electrode 400 and the blocking insulating film 330 above the device isolation film 200 may be lower than a surface of the semiconductor substrate 100, that is, an uppermost surface of the active region 150. Accordingly, the nonvolatile memory device according to the inventive concept may have the active region 150, which has a 2-dimensional (2D) layout substantially similar to a conventional memory device, and a 3D structure, which increases an effective channel width of the active region 150. This is because the active region 150 acting as a channel region includes both the surface of the semiconductor substrate 100 and sidewalls of the device isolation film 200.

Accordingly, program and erase efficiency and cell current characteristics during a read operation may be increased. Since the size of a cell may be reduced, the degree of integration may be increased. That is, since the active region is more expanded than a plane, a relative area may be increased, thereby increasing the degree of integration and forming an effectively isolated unit device.

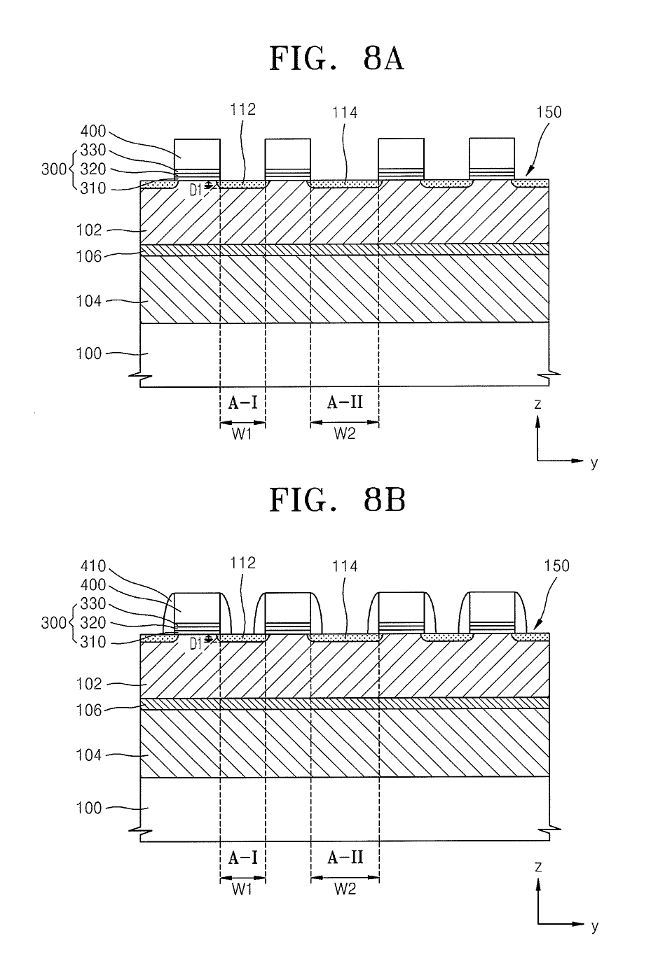

FIGS. 8A through 10C are cross-sectional views showing the same location as that of FIG. 7B after a subsequent process is performed. That is, FIGS. 8A through 10C are cross-sectional views taken along line Y-Y′ of FIG. 7A after a subsequent process is performed.

FIG. 8A is a cross-sectional view illustrating an operation of forming a first impurity region 112 and a second impurity region 114, according to an embodiment of the inventive concept.

Referring to FIG. 8A, the first impurity region 112 and the second impurity region 114 each having the second conductivity type are formed respectively in the first region A-I and the second region A-II of the active region 150 which are exposed by the gate electrode 400. The first impurity region 112 and the second impurity region 114 may be formed to a first depth D1, which is a relatively shallow junction depth, from a surface of the active region 150 exposed by the gate electrode 400. That is, each of the first impurity region 112 and the second impurity region 114 may have a thickness corresponding to the first depth D1 from the surface of the active region 150.

The first impurity region 112 and the second impurity region 114 may be formed by, for example, ion implantation, diffusion, or a combination thereof. When ion implantation is performed to form the first impurity region 112 and the second impurity region 114, if ion implantation is performed under an inclined angle or implanted ions collide or scatter, a part of the first impurity region 112 and the second impurity region 114 may overlap with a lower portion of the gate electrode 400. Alternatively, when diffusion is performed to form the first impurity region 112 and the second impurity region 114, a part of the first impurity region 112 and the second impurity region 114 may overlap with a lower portion of the gate electrode 400. Accordingly, the first impurity region 112 and the second impurity region 114 may be formed to have a width slightly greater than the first width W1 and the second width W2.

FIG. 8B is a cross-sectional view illustrating an operation of forming a spacer layer 410, according to an embodiment of the inventive concept.

Referring to FIG. 8B, the spacer layer 410 covering side surfaces of the gate electrode 400 and the charge storage structure 300 is formed. The spacer layer 410 may be formed not to completely cover the first region A-I and the second region A-II. The spacer layer 410 may include, for example, a nitride. The spacer layer 410 may be formed by, for example, forming a previous spacer layer (not shown) covering an entire surface of the semiconductor substrate 100 and performing an etch back process to expose the gate electrode 400 and the active region 150.

After the spacer layer 410 is formed, an exposed portion of the first impurity region 112 may be narrower than an exposed portion of the second impurity region 114. As will be explained later, an unexposed portion of the first impurity region 112 may be used as a source region of the nonvolatile memory device, and both an unexposed portion and the exposed portion of the second impurity region 114 may be used as a drain region of the nonvolatile memory device.

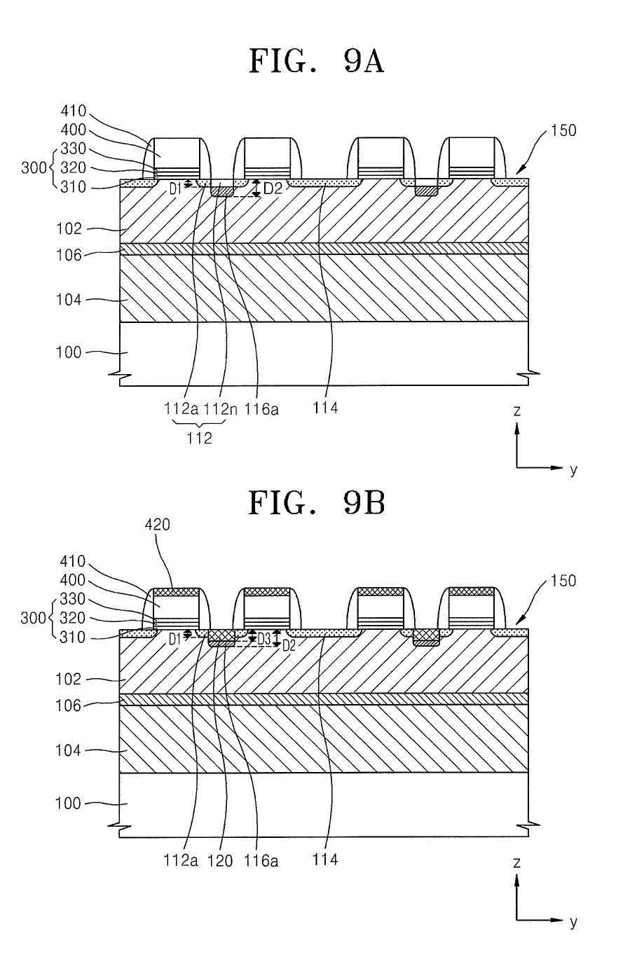

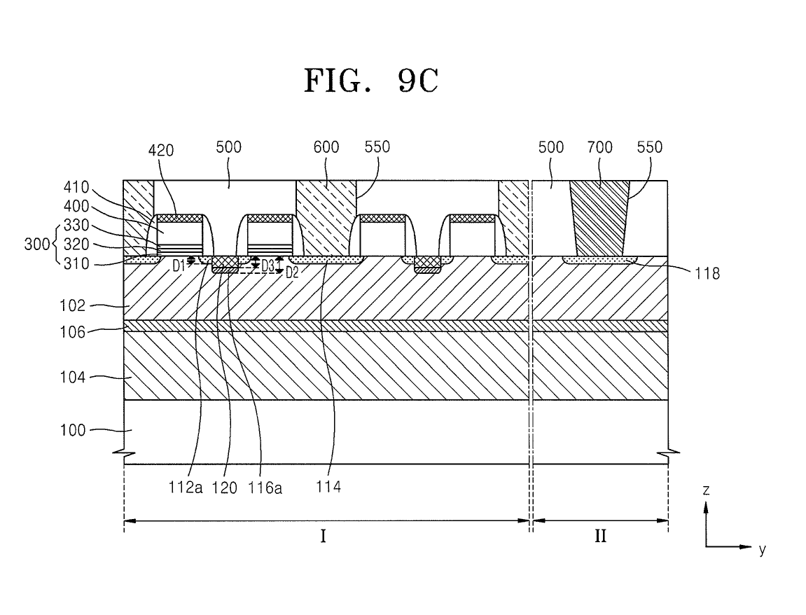

FIG. 9A is a cross-sectional view illustrating an operation of &inning a third impurity region 116a, according to an embodiment of the inventive concept.

Referring to FIG. 9A, impurities having the first conductivity type are injected through the exposed portion of the first impurity region 112 illustrated in FIG. 8B to foam the third impurity region 116a. To form the third impurity region 116a, the impurities having the first conductivity type may be injected to a second depth D2, which is greater than the first depth D1 that is the junction depth of the first impurity region 112, from the surface of the active region 150. As a result, an unexposed portion of the first impurity region 112 illustrated in FIG. 8B may remain as a source region 112a having the second conductivity type, and the exposed portion of the first impurity region 112 may be a compensation region 112n.

For example, ion implantation may be performed to form the third impurity region 116a. When ion implantation is performed to form the third impurity region 116a, the spacer layer 410 may act as a mask for preventing impurities having the first conductivity type from being injected into the source region 112a.

The third impurity region 116a may be formed under a lower surface of the first impurity region 112 to have the first conductivity type, and may be formed to have a carrier concentration higher than a carrier concentration of the pocket well region 102. The third impurity region 116a and the pocket well region 102 may form a high-low junction.

A carrier concentration of the compensation region 112n is determined according to the concentration of impurities injected to form the third impurity region 116a. The compensation region 112n may have the second conductivity type and a carrier concentration lower than that of the source region 112a or the first conductivity type and a carrier concentration lower than that of the third impurity region 116a.

While the third impurity region 116a is formed, impurities may be prevented from being injected into the second impurity region 114 due to a mask layer (not shown) such as, for example, a photoresist.

FIG. 9B is a cross-sectional view illustrating an operation of forming a metal silicide layer 120, according to an embodiment of the inventive concept.

Referring to FIG. 9B, the metal silicide layer 120 contacting the source region 112a and the third impurity region 116a may be formed. The metal silicide layer 120 may be formed by forming a refractory metal layer (not shown) formed of, for example, titanium, cobalt, or nickel, on the compensation region 112n illustrated in FIG. 9A, and then performing, for example, rapid heat treatment to cause the refractory metal layer to react with silicon.

In the present embodiment, the metal silicide layer 120 may be formed to a third depth D3, which is equal to or greater than the first depth D1 that is the junction depth of the source region 112a, from the surface of the active region 150. That is, the metal silicide layer 120 may have a thickness corresponding to the third depth D3 from the surface of the active region 150. Accordingly, the thickness of the metal silicide layer 120 may be greater than a thickness of the source region 112a. However, the metal silicide layer 120 may be formed to a depth less than the second depth D2. Since the metal silicide layer 120 is formed by reaction between a metal and silicon, a part of the metal silicide layer 120 may also be formed in a lower portion of the spacer layer 410. Accordingly, the metal silicide layer 120 may directly contact the source region 112a and the third impurity region 116a. Also, the metal silicide layer 120 may continuously extend while directly contacting the source region 112a and the third impurity region 116a.

If the gate electrode 400 is formed of doped polysilicon, a polycide layer 420 may be formed on the gate electrode 400. The metal silicide layer 120 and the polycide layer 420 may be formed of, for example, self-aligned silicide (salicide). For example, the metal silicide layer 120 and the polycide layer 420 may be farmed of salicide by forming a refractory metal layer (not shown) on the semiconductor substrate 100, performing rapid heat treatment to cause the refractory metal layer to react with silicon, and removing a portion of the refractive metal layer remaining on the spacer layer 410 by using wet etching.

In general, a metal silicide layer formed on an active region is used to increase contact resistance between the active region and a contact plug. However, the metal silicide layer 120 of the present embodiment is used to electrically connect the pocket well region 102 and the source region 112a having the second conductivity type. For example, if the first conductivity type is a p-type, the metal silicide layer 120 may electrically connect the source region 112a whose conductivity type is an n+-type and the pocket well region 102 whose conductivity type is a p-type by means of the third impurity region 116a whose conductivity type is a p+-type. Accordingly, the third impurity region 116a may be used as a pocket well junction region. That is, the metal silicide layer 120 may act as a butting contact for connecting an n+-type region and a p+-type region.

Since the metal silicide layer 120 acting as a butting contact for electrically connecting the pocket well region 102 and the source region 112a may be formed by, for example, a silicide process or a salicide process, a complex process does not need to be added.

Although not shown, a metal silicide contacting the second impurity region 114 may be formed separately from or together with the metal silicide layer 120 or the polycide layer 420.

FIG. 9C is a cross-sectional view illustrating an operation of forming a bit line contact plug 600 and a well contact plug 700, according to an embodiment of the inventive concept.

Referring to FIG. 9C, the semiconductor substrate 100 includes a base region I and an extended region II. The base region I may be the same region as a region illustrated in FIGS. 1 through 9B. The extended region II is a region extending from the base region I. Although the base region I and the extended region II appear to be separated from each other, the pocket well region 102, the isolation well region 106, and the deep well region 104 may continuously extend from the extended region II to the base region I, respectively.

Referring to FIGS. 9B and 9C, an interlayer insulating layer 500 is foamed on the semiconductor substrate 100 illustrated in FIG. 9B to cover all of the gate electrode 400 and the exposed active region 150. A fourth impurity region 118 having the first conductivity type of the extended region II is formed in a part of the pocket well region 102, before the interlayer insulating layer 500 is formed. A carrier concentration of the fourth impurity region 118 may be higher than a carrier concentration of the pocket well region 102.

Next, a part of the interlayer insulating layer 500 may be removed to form a contact hole 550 through which the second impurity region 114 and the fourth impurity region 118 are exposed. A portion of the contact hole 550 through which the second impurity region 114 is exposed may be self-aligned.

The bit line contact plug 600 and the well contact plug 700 are formed by filling a conductive material in the contact hole 550 through which the second impurity region 114 and the fourth impurity region 118 are exposed.

The bit line contact plug 600 may be electrically connected to the second impurity region 114, that is, a drain region of the nonvolatile memory device, to supply a voltage to the drain region through a bit line (not shown). The well contact plug 700 may be electrically connected to the pocket well region 102 through the fourth impurity region 118, to supply a voltage to the pocket well region 102. A voltage supplied to the pocket well region 102 through the well contact plug 700 may be a bulk voltage VB in the nonvolatile memory device. Also, a voltage supplied to the pocket well region 102 through the well contact plug 700 may be a source voltage Vs supplied to the source region 112a through the metal silicide layer 120. The bit line contact plug 600 and the second impurity region 114 may directly contact each other, or may contact each other with a metal silicide (not shown) therebetween to reduce contact resistance. Also, the well contact plug 700 and the fourth impurity region 118 may directly contact each other, or may contact each other with a metal silicide (not shown) therebetween to reduce contact resistance.

Accordingly, the nonvolatile memory device of the present embodiment may apply the bulk voltage Vb and the source voltage Vs as the same voltage due to the metal silicide layer 120 acting as a butting contact. Also, the source region 112a may be a buried source not exposed by the gate electrode 400 and the spacer layer 410.

In consideration of contact resistance between the bit line contact plug 600 and the second impurity region 114 and a process margin required to form the contact hole 550 and fill a conductive material in the contact hole 550, a space between adjacent gate electrodes 400 with the second impurity region 114 therebetween should be large. However, the nonvolatile memory device according to the present embodiment does not need to form a separate contact plug for supplying a voltage to the source region 112a. Accordingly, a space between adjacent gate electrodes 400 with the source region 112a therebetween may be minimized.

Also, since a separate contact plug for supplying a voltage to the source region 112a does not need to be formed, a wiring line connected to the separate contact plug does not need to be formed. Accordingly, only a wiring line, that is, a bit line, connected to the bit line contact plug 600 for supplying a voltage to the drain region, that is, the second impurity region 114 should be fowled. Accordingly, a pitch for forming a wiring line may be reduced by about half. Accordingly, the nonvolatile memory device according to the present embodiment may achieve a high degree of integration.

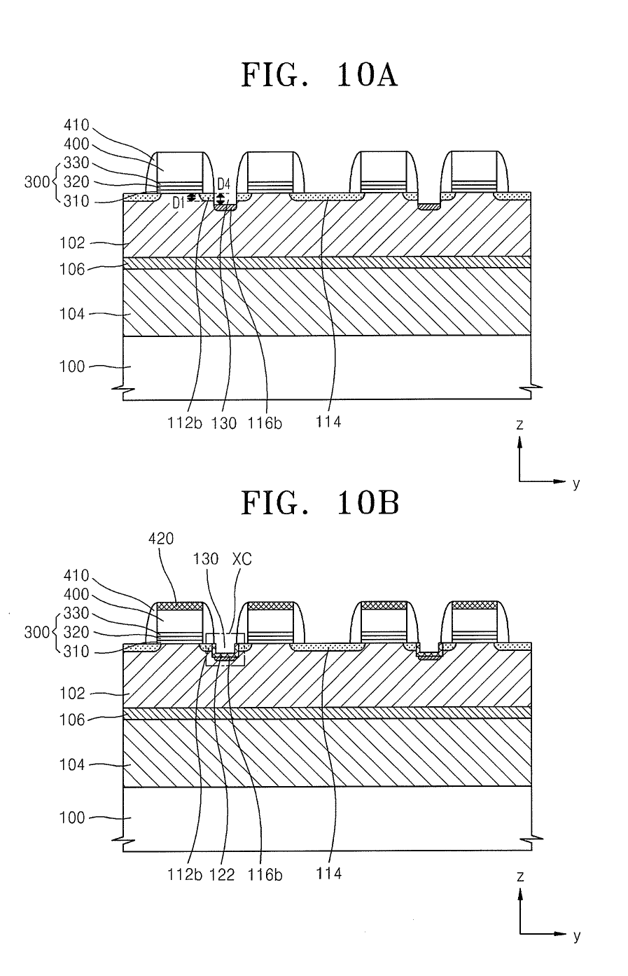

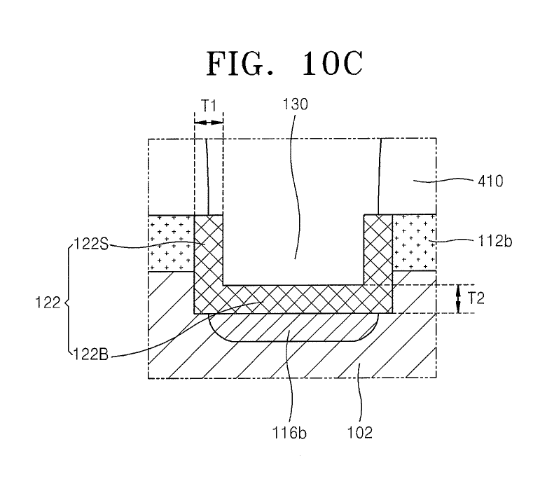

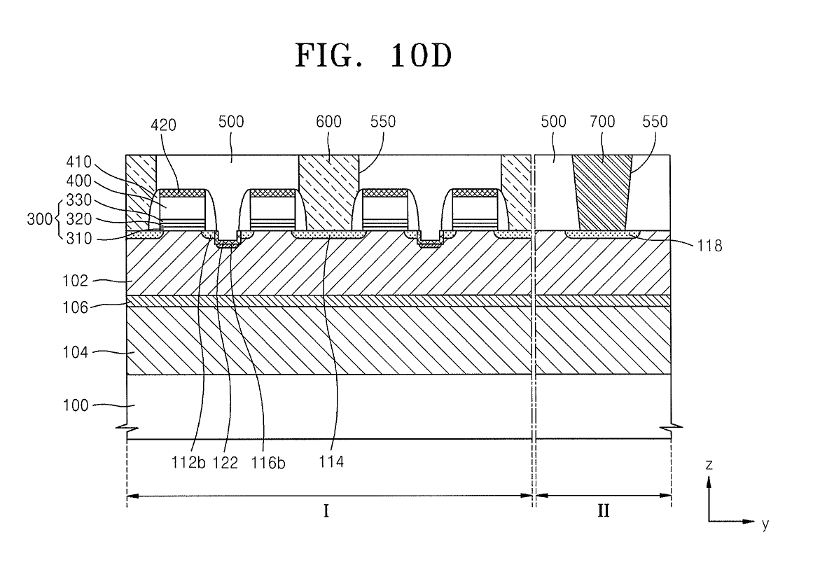

FIGS. 10A through 10C are cross-sectional views illustrating an operation of forming a third impurity region 116b and a metal silicide layer 122, according to an embodiment of the inventive concept. FIGS. 10A through 10C are cross-sectional views illustrating a subsequent operation after FIG. 8B.

FIG. 10A is a cross-sectional view illustrating an operation of forming the third impurity region 116b, according to an embodiment of the inventive concept.

Referring to FIG. 10A, a second recess region 130 is formed by removing the first impurity region 112 exposed between two facing spacer layers 410 in the first region A-I illustrated in FIG. 8B. The second recess region 130 may be formed to a fourth depth D4, which is equal to or greater than the first depth D1 that is the depth of the first impurity region 112, to expose the pocket well region 102. That is, the fourth depth D4, which is a depth of the second recess region 130, may be equal to or greater than the first depth D1. As a result, an unexposed portion of the first impurity region 112 illustrated in FIG. 8B remains as a source region 112b having the second conductivity type, and an exposed portion of the first impurity region 112 is removed. For example, dry etching or etch back may be performed to form the second recess region 130. If a thickness of the gate electrode 400 is greater than a depth of the second recess region 130, a separate mask layer may not be formed on the gate electrode 400.

Next, the third impurity region 116b is formed in an exposed portion under a lower surface of the second recess region 130 by injecting impurities having the first conductivity type through the second recess region 130. The third impurity region 116b may be formed to have a carrier concentration higher than a carrier concentration of the pocket well region 102.

While the third impurity region 116b is formed, impurities may be prevented from being injected into the second impurity region 114 due to a mask layer (not shown) such as, for example, a photoresist.

FIG. 10B is a cross-sectional view illustrating an operation of forming the metal silicide layer 122, according to an embodiment of the inventive concept.

Referring to FIG. 10B, the metal silicide layer 122 contacting the source region 112b and the third impurity region 116b may be formed. The metal silicide layer 122 may be formed by forming a refractory metal layer (not shown) formed of, for example, titanium, cobalt, or nickel, on an inner surface of the second recess region 130 illustrated in FIG. 10B and performing, for example, rapid heat treatment to cause the refractory metal layer to react with silicon. Accordingly, the second recess region 130 may be defined by the metal silicide layer 122.

Since the metal silicide layer 122 is formed due to reaction between a metal and silicon, a part of the metal silicide layer 122 may also be formed in a lower portion of the spacer layer 410. Accordingly, the metal silicide layer 122 may directly contact the source region 112b and the third impurity region 116b.

If the gate electrode 400 is formed of doped polysilicon, the polycide layer 420 may be formed on the gate electrode 400. The metal silicide layer 120 and the polycide layer 420 may be formed of, for example, salicide. For example, the metal silicide layer 122 and the polycide layer 420 may be formed of salicide by forming a refractory metal layer (not shown) on the semiconductor substrate 100, performing rapid heat treatment to cause the refractory metal layer to react with silicon, and removing a portion of the refractory metal layer remaining on the spacer layer 410 by using wet etching.

The metal silicide layer 122 according to the present embodiment is used to electrically connect the pocket well region 102 and the source region 112b having the second conductivity type. For example, if the first conductivity type is a p-type, the metal silicide layer 122 may electrically connect the source region 112b whose conductivity type is an n+-type and the pocket well region 102 whose conductivity type is a p-type by means of the third impurity region 116b whose conductivity type is a p+-type. Accordingly, the third impurity region 116b may be used as a pocket well junction region. That is, the metal silicide layer 122 may act as a butting contact for connecting an n+-type region and a p+-type region.

Although not shown, a metal silicide contacting the second impurity region 114 may be formed separately from or together with the metal silicide layer 122 or the polycide layer 420.

FIG. 10c is an enlarged cross-sectional view illustrating an operation of forming the metal silicide layer 122, according to an embodiment of the inventive concept. In detail, FIG. 10C is an enlarged cross-sectional view illustrating an XC portion of FIG. 10B.

Referring to FIG. 10C, the metal silicide layer 122 may include, for example, a sidewall portion 122S contacting the source region 112b, and a bottom surface portion 122B contacting the third impurity region 116b, that is, a pocket well junction region. Accordingly, the recess region 130 may be defined by the sidewall portion 122S and the bottom surface portion 122B.

A first thickness T1 which is a thickness of the sidewall portion of the metal silicide layer 122 contacting the source region 112b and a second thickness T2 which is a thickness of the bottom surface portion 122B of the metal silicide layer 122 contacting the third impurity region 116b may be different from each other.

The source region 112b and the third impurity region 116b may have different conductivity types. Accordingly, because the source region 112b and the third impurity region 116b have different conductivity types, thicknesses of the sidewall portion 122S and the bottom surface portion B of the metal silicide layer 122 may be different from each other. For example, if the source region 112b has a conductivity type that is an n⁺ type and the third impurity region 116b has a conductivity type that is a p⁺ type, the first thickness T1 which is the thickness of the sidewall portion 122S may be less than the second thickness T2 which is the thickness of the bottom surface portion 122B.

Alternatively, a thickness of the refractory metal layer for forming the metal silicide layer 122 on a side surface of the recess region 130 may be less than a thickness of the refractory metal layer on a lower surface of the recess region 130. Accordingly, a thickness of the sidewall portion 122S of the metal silicide layer 122 formed on a sidewall of the recess region 130 may be less than a thickness of the bottom surface portion 122B of the metal silicide layer 122 formed on the lower surface of the recess region 130.

FIG. 10D is a cross-sectional view illustrating an operation of forming the bit line contact plug 600 and the well contact plug 700, according to an embodiment of the inventive concept. FIG. 10D is very similar to FIG. 9C except for the shape of the metal silicide layer 122, and thus a repeated explanation thereof will not be given.

Referring to FIG. 10D, the semiconductor substrate 100 includes the base region I and the extended region II. The base region I may be the same region as a region illustrated in FIGS. 1 through 8B and 10A and 10B. The extended region II is a region extending from the base region I. Although the base region I and the extended region II appear to be separated from each other, the pocket well region 102, the isolation well region 106, and the deep well region 104 may continuously extend from the base region I to the extended region II, respectively.

Referring to FIGS. 10B and 10C, the interlayer insulating layer 500 is formed on the semiconductor substrate 100 illustrated in FIG. 10B to cover all of the gate electrode 400 and the exposed active region 1050. Next, the contact hole 550 through which the second impurity region 114 and the fourth impurity region 118 are exposed may be formed by removing a part of the interlayer insulating layer 500. The bit line contact plug 600 and the well contact plug 700 are formed by filling a conductive material in the contact hole through which the second impurity region 114 and the fourth impurity region 118 are exposed.

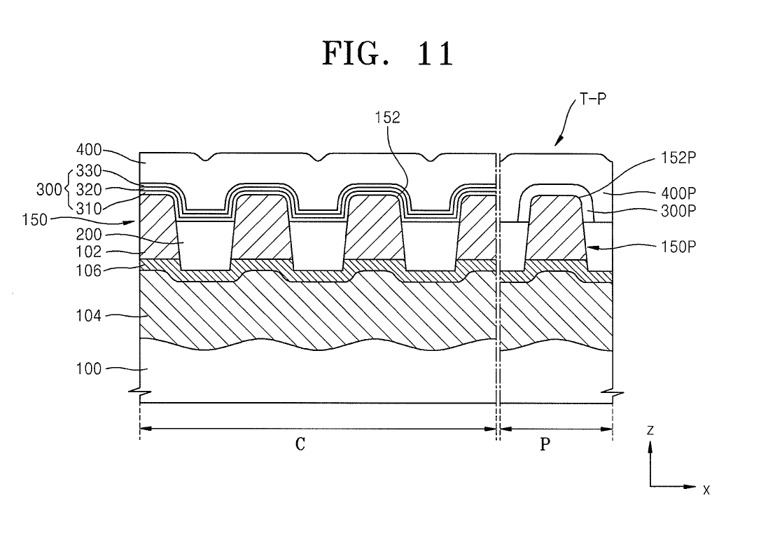

FIG. 11 is a cross-sectional view illustrating an operation of forming a high voltage transistor T-P, according to an embodiment of the inventive concept.

Referring to FIG. 11, the semiconductor substrate 100 includes a cell region C and a core/peripheral circuit region P. The cell region C may be the same region as a region illustrated in FIG. 7A. The cell region C is a region where memory cells of the nonvolatile memory device are formed. The core/peripheral circuit region P is a region where circuit devices necessary for driving the nonvolatile memory device and selecting each memory cell are formed or nonvolatile semiconductor devices are formed.

The cell region C and the core/peripheral circuit region P illustrated in FIG. 11 may be regions extending on the semiconductor substrate 100 like the base region I and the extended region II illustrated in FIG. 9C or FIG. 10C, but the pocket well region 102, the isolation well region 106, and the deep well region 104 of the cell region C and the core/peripheral circuit region P may not continuously extend unlike the base region I and the extended region II. Alternatively, some of the pocket well region 102, the isolation well region 106, and the deep well region 104 may not be formed.

The high voltage transistor T-P may be formed in the core/peripheral circuit region P. An active region 150P, a gate insulating film 300P, and a gate electrode 400P may be formed to constitute the high voltage transistor T-P.

Like the active region 150 of the cell region C, the active region 150P of the high voltage transistor T-P may protrude beyond the device isolation film 200. The active region 150P of the high voltage transistor T-P may protrude beyond the device isolation film 200 when being formed along with the active region 150 of the cell region C.

Edges of the active region 150P of the high voltage transistor T-P protruding beyond the device isolation film 200 like the active region 150 of the cell region C may be rounded to form round edges 152P. The active region 150P of the high voltage transistor T-P may have the round edges 152P when being formed along with the active region 150 of the cell region C.

Some or all of the pocket well region 102, the isolation well region 106, and the deep well region 104 may not be formed or other well or impurity regions may be formed in the core/peripheral circuit region P. Also, the gate insulating film 300P of the high voltage transistor T-P may be formed separately from or together with the charge storage structure 300, which may be selected in such a manner that requirements for the high voltage transistor T-P are satisfied.

In the core/peripheral circuit region P, separate processes may be performed in the cell region C. That is, after only one region of the core/peripheral circuit region P and the cell region C is exposed by using a mask pattern, individual processes may be performed. However, if the active region 150P of the high voltage transistor T-P is formed along with the active region 150 of the cell region C, the performance of the high voltage transistor T-P may be increased and a process may be simplified.

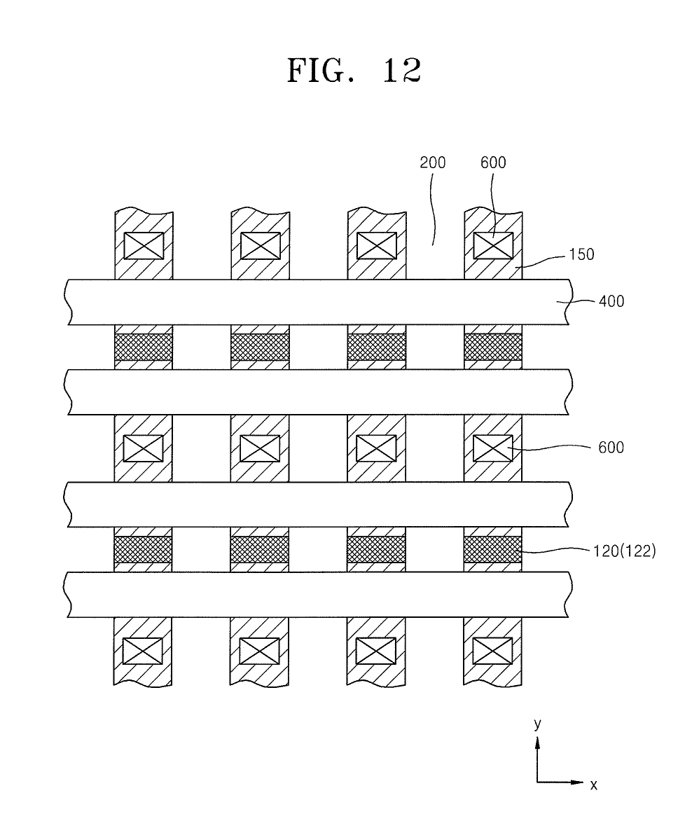

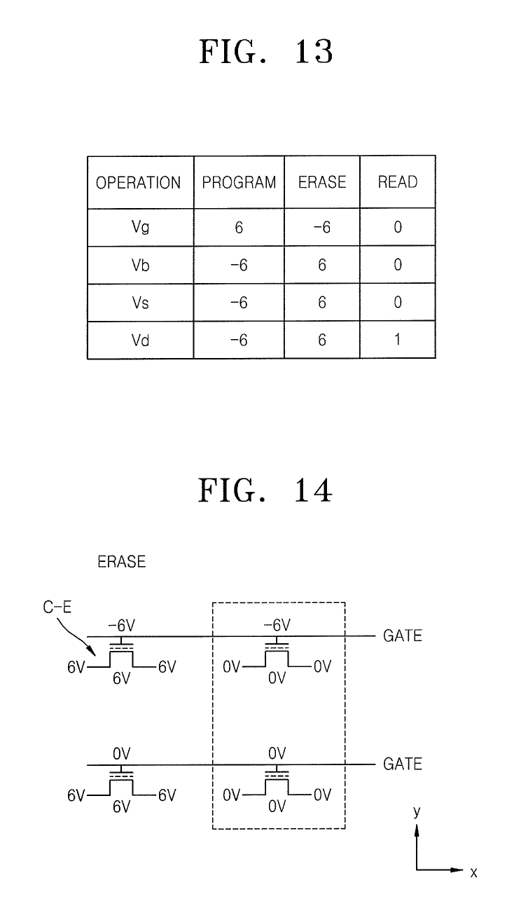

FIG. 12 is a plan view illustrating a positional relationship between the device isolation film 200, the active region 150, the bit line contact plug 600, the metal silicide layer 120 or 122, and the gate electrode 400, according to an embodiment of the inventive concept.

FIG. 12 is a plan view illustrating a positional relationship between the device isolation film 200, the active region 150, the bit line contact plug 600, the metal silicide layer 120 or 122, and the gate electrode 400, but is not for illustrating a specific operation. Accordingly, elements, such as the spacer layer 410, the interlayer insulating layer 500, the first impurity region 112, and the second impurity region 114, are not shown.

Referring to FIG. 12, a plurality of the active regions 150 and a plurality of the gate electrodes 400 are formed to intersect each other. For example, gate electrode 400 may extend in a first direction (x direction) and each active region 150 may extend in a second direction (y direction) which is different from the first direction. Accordingly, the plurality of gate electrodes 400 may be formed on one active region 150 to intersect the active region 150, and the plurality of active regions 150 may be arranged in the first direction which is a direction in which the gate electrodes 400 extend. Accordingly, a plurality of the bit line contact plugs 600 and a plurality of the metal silicide layers 120 or 122 may be alternately disposed on the active regions 150 exposed by the gate electrodes 400.

A plurality of unit cells of the nonvolatile memory device may be arranged at intersections between the active regions 150 and the gate electrodes 400 to form a cell array. The unit cells may be portions of the charge storage layer 320 illustrated in FIGS. 7A through 11 located at intersections between the active regions 150 and the gate electrodes 400. From among the plurality of unit cells, unit cells arranged in the first direction may share the gate electrodes 400, and unit cells arranged in the second direction may share the active regions 150.

FIG. 13 is a table illustrating operating voltages for explaining a method of driving the nonvolatile memory device, according to an embodiment of the inventive concept.

Referring to FIG. 9C or 10C, and FIG. 13, voltages for a program operation, an erase operation, and a read operation for each unit cell of the nonvolatile memory device are a gate voltage Vg, a bulk voltage Vb, a source voltage Vs, and a drain voltage Vd. The gate voltage Vg refers to a potential applied to the gate electrode 400. The bulk voltage Vb refers to a potential applied to the pocket well region 102. The source voltage Vs refers to a potential applied to the source region 112a or 112b. The drain region Vd refers to a potential applied to the second impurity region 114a that is a drain region.

When data is programmed in the unit cell, the bulk voltage Vb and the source voltage Vs are applied as the same potential. The bulk voltage Vb and the source voltage Vs refer to potentials applied to the pocket well region 102 and the source region 112a or 112b, respectively. The pocket well region 102 and the source region 112a or 112b are brought into butting contact with each other by means of the metal silicide layer 120 or 122. Accordingly, the same potential may be supplied to the pocket well region 102 and the source region 112a or 112b, without being supplied separately to the pocket well region 102 and the source region 112a or 112b.

Here, the same potential does not mean the completely same potential, but means an identical or similar potential as long as a program operation, an erase operation, and a read operation may be normally performed for each unit cell. Accordingly, the same potential may be a potential in a range that allows an operation for each unit cell to be normally performed even though there is a difference between potentials due to the parasitic resistance of each element and contact resistance between elements.

When data is programmed in the unit cell, the gate voltage Vg has a potential having a polarity opposite to that of the bulk voltage Vb or the source voltage Vs. Also, when data is programmed in the unit cell, the drain voltage Vd may have an identical or similar potential to that of the bulk voltage Vb or the source voltage Vs. The drain voltage Vd, which is a potential applied to the second impurity region 114 that is a drain region, may be separately applied from the bulk voltage Vb or the source voltage Vs.

For example, if the first conductivity type is a p-type, a potential of −6 V may be applied as the bulk voltage Vb and the source voltage Vs. Also, potentials of, for example, 6 V and −6 V may be respectively applied as the gate voltage Vg and the drain voltage Vd.

When data programmed and stored in the unit cell is erased, a potential having a polarity opposite to that used when data is programmed in the unit cell is supplied. Accordingly, when data programmed and stored in the unit cell, the bulk voltage Vb and the source voltage Vs may have the same potential. When data programmed and stored in the unit cell is erased, the gate voltage Vg has a potential having a polarity opposite to that of the bulk voltage Vb or the source voltage Vs. Also, when data programmed and stored in the unit cell is erased, the drain voltage Vd may have an identical or similar potential to that of the bulk voltage Vb or the source voltage Vs.

For example, if the first conductivity type is a p-type, a potential of 6 V may be applied as the bulk voltage Vb and the source voltage Vs. Also, potentials of, for example, −6 V and 6 V may be respectively applied as the gate voltage Vg and the drain voltage Vd.

On the other hand, when data programmed and stored in the unit cell is read, the drain voltage Vd may have a potential different from those of the bulk voltage Vd and the source voltage Vs. In this case, the drain voltage Vd may have a potential whose absolute value is less than that of a potential applied during a program operation or an erase operation.

For example, if the first conductivity type is a p-type, a potential of 0 V may be supplied to the bulk voltage Vb and the source voltage Vs. Also, potentials of, for example, 0 V and 1 V may be respectively applied as the gate voltage Vg and the drain voltage Vd.

Accordingly, the same potential is applied as the bulk voltage Vd and the source voltage Vs during all operations of the nonvolatile memory device. Since the pocket well region 102 and the source region 112a and 112b are brought into butting contact with each other by means of the metal silicide layer 120 or 122, the same potential may be supplied to the pocket well region 102 and the source region 112a or 112b without being separately supplied to the pocket well region 102 and the source region 112a or 112b.

Although the gate voltage Vg, the bulk voltage Vb, the source voltage Vs, and the drain voltage Vd represent relative potentials herein, the present embodiment is not limited thereto. Also, potentials may have polarities opposite to those illustrated in FIG. 13 according to the first and second conductivity types. If potentials having opposite polarities are applied, that is, if a gate voltage Vg having a polarity opposite to those of the source voltage Vs and the bulk voltage Vd is applied during a program operation or an erase operation, the absolute value of a potential of the gate voltage Vg may be the same as or different from those of potentials of the source voltage Vs and the bulk voltage Vb.

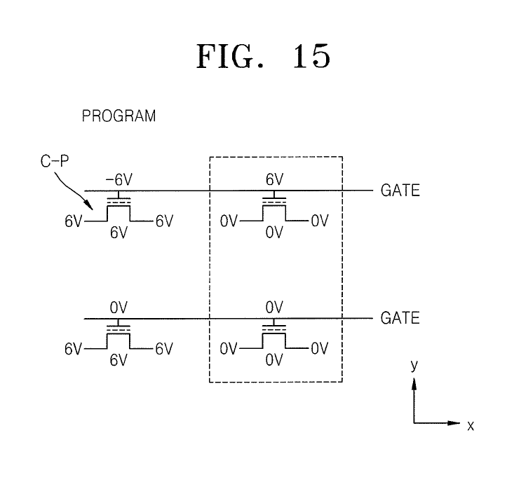

FIGS. 14 and 15 are conceptual views illustrating potentials applied to an adjacent unit cell when a selected unit cell of the nonvolatile memory device is driven, according to an embodiment of the inventive concept. Directions in FIGS. 14 and 15 are a direction in which gates extend and a direction in which unit cells are arranged, and others in FIGS. 14 and 15 are just used for convenience of illustration and are deemed to be irrelevant.

FIG. 14 is a conceptual view illustrating potentials applied to an adjacent unit cell when data programmed in a selected unit cell C-E of the nonvolatile memory device is erased, according to an embodiment of the inventive concept.

Referring to FIG. 14, the same potential is applied to a source, a drain, and a bulk and a potential having an opposite polarity is applied to a gate of the selected unit cell C-E during an erase operation.

The same potential as that applied to the gate of the selected unit cell C-E may be applied to a gate of an adjacent unit cell that shares the same gate with the selected unit cell C-E, that is, a unit cell adjacent to the selected unit cell C-E in a first direction (x direction) or a reverse direction (−x direction), and a potential different from those of the source, the drain, and the bulk of the selected unit cell C-E may be applied to a source, a drain, and a bulk of the adjacent unit cell. For example, if potentials of 6 V, 6 V, 6V, and −6 V are respectively applied to the source, the drain, the bulk, and the gate of the selected unit cell C-E, potentials of 0 V, 0 V, 0 V, and −6 V may be applied to the source, the drain, the bulk, and the gate of the adjacent unit cell that shares the same gate with the selected unit cell C-E.

The same potential as that applied to the source and the bulk of the selected unit cell C-E may be applied to a source and a bulk of an adjacent unit cell that shares an active region with the selected unit cell C-E, that is, a unit cell that is adjacent to the selected unit cell C-E in a second direction (y direction) or a reverse direction (−y direction). A potential may be applied via the same wiring line to drains of unit cells sharing the active region with the selected unit cell C-E. Accordingly, the same potential as that applied to the drain of the selected unit cell C-E may be supplied to a drain of the adjacent unit cell that shares the active region with the selected unit cell C-E. A potential different from that of the gate of the selected unit cell C-E may be applied to a gate of the adjacent unit cell that shares the same active region with the selected unit cell C-E. For example, if potentials of 6 V, 6 V, 6 V, and −6 V are respectively applied to the source, the drain, the bulk, and the gate of the selected unit cell C-E, potentials of 6 V, 6 V, 6 V, and 0 V may be applied to the source, the drain, the bulk, and a gate of the adjacent unit cell that share the active region with the selected unit cell C-E.

An adjacent unit cell that does not share the active region and the gate with the selected unit cell C-E, that is, an adjacent unit cell that is adjacent to the selected unit cell C-E in a direction other than the first direction and the second direction, shares an active region with the adjacent unit cell sharing the same gate with the selected unit cell C-E, and shares a gate with the adjacent unit cell sharing the active region with the selected unit cell C-E. Accordingly, potentials different from those supplied to the source, the drain, the bulk, and the gate of the selected unit C-E may be supplied to a source, a drain, a bulk, and a gate of an adjacent unit cell that does not share the active region and the gate with the selected unit cell C-E. For example, if potentials of 6 V, 6 V, 6 V, and −6 V are respectively applied to the source, the drain, the bulk, and the gate of the selected unit cell C-E, potentials of 0 V, 0 V, 0 V, and 0 V may be applied to the source, the drain, the bulk, and the gate of the adjacent unit cell that does not share the active region and the gate with the selected unit cell C-E.

Accordingly, the same potential is applied to sources, drains, and bulks of all adjacent unit cells that are adjacent to the selected unit cell C-E. Accordingly, since there is no potential difference between a drain and a bulk, a disturbance which may occur in adjacent unit cells that are adjacent to the selected unit cell C-E may be prevented. Accordingly, although it is difficult to reduce the size of a unit cell when a disturbance occurs, since the disturbance may be prevented, the size of a unit cell may be easily reduced.

FIG. 15 is a conceptual view illustrating potentials applied to an adjacent cell when data is programmed in a selected unit cell C-P of the nonvolatile memory device, according to an embodiment of the inventive concept.

Referring to FIG. 15, the same potential is applied to a source, a drain, and a bulk and a potential having an opposite polarity is applied to a gate of the selected unit cell C-P during a program operation as described with reference to FIG. 13. During the program operation, potentials having polarities opposite to those applied during the erase operation illustrated in FIG. 14 may be applied. Accordingly, since a potential having an opposite polarity may also be applied to a unit cell adjacent to the selected unit cell C-P, a detailed explanation thereof will not be given.

For example, potentials of −6 V, −6 V, −6 V, and 6 V are respectively applied to the source, the drain, the bulk, and the gate of the selected unit cell C-P, potentials of 0 V, 0 V, 0 V, and 6 V may be applied to a source, a drain, a bulk, and a gate of an adjacent unit cell that shares the same gate with the selected unit cell C-P. Potentials of, for example, −6 V, −6 V, −6 V, and 0 V may be applied to a source, a drain, a bulk, and a gate of an adjacent unit cell that shares an active region of the selected unit cell C-P. Also, potentials of, for example, 0 V, 0 V, 0 V, and 0 V may be applied to a source, a drain, a bulk, and a gate of an adjacent unit cell that does not share the active region and the gate with the selected unit cell C-P.

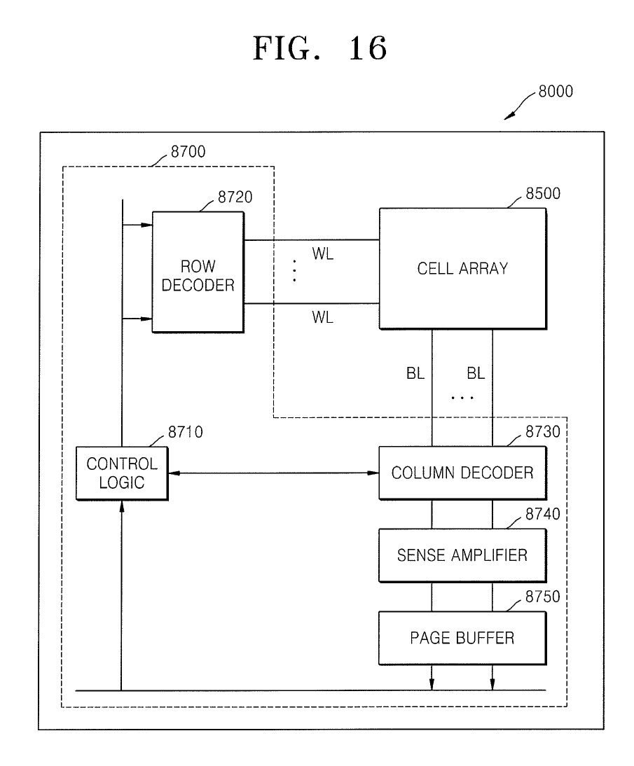

FIG. 16 is a block diagram of a nonvolatile memory device 8000 according to an embodiment of the inventive concept.

Referring to FIG. 16, in the nonvolatile memory device 8000, a cell array 8500 may be coupled to a core circuit unit 8700. For example, the cell array 8500 may be a cell array including unit cells of the nonvolatile memory device described with reference to FIG. 12. The core circuit unit 8700 may include, for example, a control logic unit 8710, a row decoder 8720, a column decoder 8730, a sense amplifier 8740, and a page buffer 8750.

The control logic unit 8710 may communicate with the row decoder 8720, the column decoder 8730, and the page buffer 8750. The row decoder 8720 may communicate with the cell array 8500 through a plurality of word lines WL. The column decoder 8730 may communicate with the cell array 8500 through a plurality of bit lines BL. The sense amplifier 8740 may be connected to the column decoder 8730 when a signal is output from the cell array 8500 and may not be connected to the column decoder 8730 when a signal is transmitted to the cell array 8500.

For example, the control logic unit 8710 may transmit a row address signal to the row decoder 8720, and the row decoder 8720 may decode the row address signal and transmit the row address signal to the cell array 8500 through the word lines WL. The control logic unit 8710 may transmit a column address signal to the column decoder 8730 or the page buffer 8750, and the column decoder 8730 may decode the column address signal and transmit the column address signal to the cell array 8500 through the plurality of bit lines BL. A signal of the cell array 8500 may be transmitted to the sense amplifier 8740 through the column decoder 8730, amplified by the sense amplifier 8740, and transmitted to the control logic unit 8710 through the page buffer 8750.

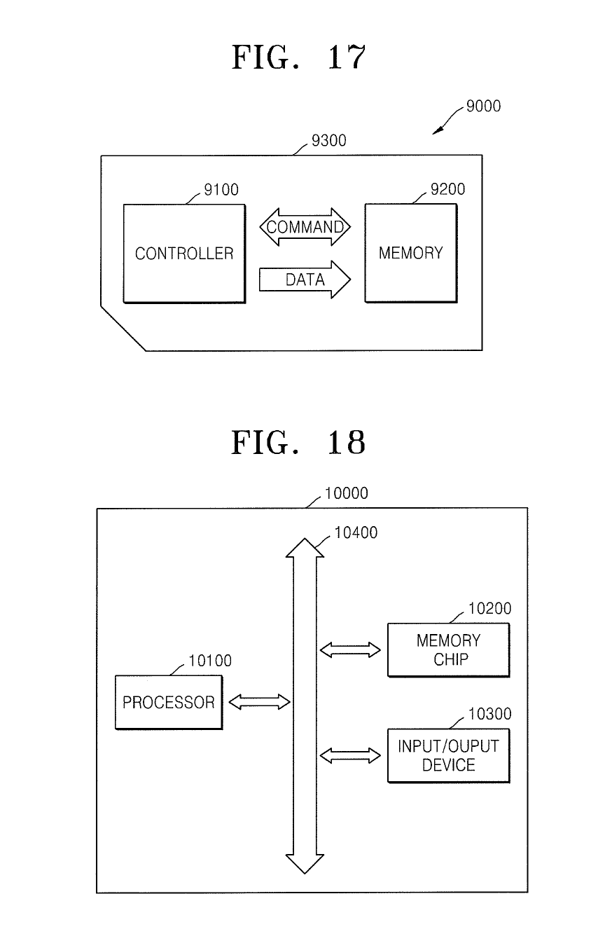

FIG. 17 is a block diagram of a memory card 9000 according to an embodiment of the inventive concept.

Referring to FIG. 17, the memory card 9000 may include, for example, a controller 9100 and a memory 9200 installed in a housing 9300. The controller 9100 and the memory 9200 may exchange an electrical signal therebetween. For example, the memory 9200 and the controller 9100 may receive and transmit data between each other according to a command of the controller 9100. Accordingly, the memory card 9000 may store data in the memory 9200 or output data from the memory 9200 to the outside.

For example, the memory 9200 may include a cell array including unit cells of the nonvolatile semiconductor device described with reference to FIG. 12. The memory card 9000 may be used as a data storage medium of various portable devices. Examples of the memory card 9000 may include, but are not limited to a multimedia card (MMC) or a secure digital (SD) card.

FIG. 18 is a block diagram of an electronic system 10000 according to an embodiment of the inventive concept.

Referring to FIG. 18, the electronic system 10000 may include, for example, a processor 10100, an input/output device 10300, and a memory chip 10200, and the processor 10100, the input/output device 10300, and the memory chip 10200 may receive and transmit data between one another via a bus 10400. The processor 10100 may execute a program and control the electronic system 10000. The input/output device 10300 may be used to input or output data of the electronic system 10000. The electronic system 10000 may exchange data with an external device by being connected to the external device, e.g., a personal computer (PC) or a network. The memory chip 10200 may store codes and data for the operation of the processor 10100. For example, the memory chip 10200 may include a cell array including unit cells of the nonvolatile semiconductor device described with reference to FIG. 12.

The electronic system 10000 may constitute various electronic control devices employing the memory chip 10200, such as for example, mobile phones, MP3 players, navigation systems, solid state disks (SSD), and household appliances.

Having described the exemplary embodiments of the inventive concept, it is further noted that it is readily apparent to those of reasonable skill in the art that various modifications may be made without departing from the spirit and scope of the invention which is defined by the metes and bounds of the appended claims.

1. A nonvolatile memory device comprising:
a device isolation film defining an active region in a semiconductor substrate;
a pocket well region formed in an upper portion of the active region and having a first conductivity type;
a gate electrode formed on the active region and extending to intersect the active region;
a tunnel insulating film, a charge storage film, and a block insulating film sequentially disposed between the active region and the gate electrode;
a source region and a drain region respectively formed in a first region and a second region of the active region exposed on both sides of the gate electrode, and each having a second conductivity type opposite to the first conductivity type;
a pocket well junction region formed in the first region adjacent to the source region and contacting the pocket well region, and having the first conductivity type; and
a metal silicide layer formed in the first region and contacting the source region and the pocket well junction region.

2. The nonvolatile memory device of claim 1, wherein the device isolation film is recessed to a predetermined depth from a surface of the semiconductor substrate, so that the active region protrudes beyond the device isolation film.

3. The nonvolatile memory device of claim 2, wherein edges of the active region protruding beyond the device isolation film are rounded.

4. The nonvolatile memory device of claim 4, wherein the pocket well region has a lowermost surface between a lower surface and an upper surface of the device isolation film.

5. The nonvolatile memory device of claim 4, further comprising:
an isolation well region contacting a lower portion of the device isolation film and a lower portion of the pocket well region, and having the second conductivity type; and
a deep well region formed under the isolation well region and having the second conductivity type.

6. The nonvolatile memory device of claim 5, wherein the isolation well region extends and contacts at least a portion of the pocket well region and at least a portion of the device isolation film.

7. The nonvolatile memory device of claim 5, wherein the isolation well region extends along a lower surface of the pocket well region, a lower surface of the device isolation film, and a side surface of the lower portion of the device isolation film,
wherein the side surface of the lower portion of the device isolation film connects the lower surface of the pocket well region and the lower surface of the device isolation film.

8. The nonvolatile memory device of claim 5, wherein the isolation well region has a carrier concentration higher than a carrier concentration of the deep well region.

9. The nonvolatile memory device of claim 5, wherein the isolation well region and the deep well region contact each other to form a high-low junction due to a relatively high carrier concentration and a relatively low carrier concentration.

10. The nonvolatile memory device of claim 5, wherein the pocket well region and the isolation well region directly contact each other to form a p-n junction.

11. The nonvolatile memory device of claim 1, wherein the metal silicide layer continuously extends from the source region to the pocket well junction region.

12. The nonvolatile memory device of claim 1, wherein the metal silicide layer comprises a sidewall portion contacting the source region and a bottom surface portion contacting the pocket well junction region in the first region, and a recess region is defined by the sidewall portion and the bottom surface portion.

13. The nonvolatile memory device of claim 12, wherein a thickness of the sidewall portion and a thickness of the bottom surface portion of the metal silicide layer are different from each other.

14. The nonvolatile memory device of claim 1, further comprising a spacer layer contacting both side surfaces of the gate electrode,
wherein the source region is located in a portion of the active region covered by the spacer layer,
the pocket well junction region is located in a portion of the active region exposed by the gate electrode and the spacer layer, and
the metal silicide layer is formed on the pocket well junction region and contacts a side surface of the source region.

15. The nonvolatile memory device of claim 1, wherein a thickness of the metal silicide layer is no less than a thickness of the source region.

16. The nonvolatile memory device of claim 1, further comprising:
an interlayer insulating layer formed on the active region and the gate electrode and completely covering the metal silicide layer;
a conductive bit line contact plug passing through the interlayer insulating layer and electrically connected to the drain region; and
a conductive well contact plug passing through the interlayer insulating layer and electrically connected to the pocket well region.

17. The nonvolatile memory device of claim 1, wherein a width of the first region is less than a width of the second region in a direction perpendicular to a direction in which the gate electrode extends.

18. A nonvolatile memory device comprising:
a semiconductor substrate defining a cell region and a core/peripheral circuit region;
an active region defined by and protruding beyond a device isolation film that is recessed to a predetermined depth from a surface of the semiconductor substrate in each of the cell region and the core/peripheral circuit region;
a gate electrode formed on the active region and extending to intersect the active region;
a pocket well region formed on an upper portion of the active region in the cell region and having a first conductivity type;
a tunnel insulating film, a charge storage film, and a blocking insulating film sequentially disposed between the active region and the gate electrode in the cell region;
a gate insulating film disposed between the active region and the gate electrode in the core/peripheral circuit region;
a source region and a drain region respectively formed in a first region and a second region of the active region exposed on both sides of the gate electrode in the cell region, and each having a second conductivity type;
a pocket well junction region formed in the first region adjacent to the source region, and having the first conductivity type; and
a metal silicide layer formed in the first region and extending to contact the source region and the pocket well junction region,
wherein the active region, the gate insulating film, and the gate electrode constitute a high voltage transistor in the core/peripheral circuit region.

19. The nonvolatile memory device of claim 18, further comprising:
an isolation well region extending along lower surfaces of the device isolation film and the pocket well region in the cell region, and having a second conductivity type opposite to the first conductivity type; and
a deep well region formed under the isolation well region in the cell region and having the second conductivity type.

20. (canceled)
